(19) United States
(12) Patent Application Publication
(10) Pub. No.: US 2025/0393127 A1
(43) Pub. Date: Dec. 25, 2025

(54) SUBSTRATE STRUCTURE AND MANUFACTURING METHOD THEREOF

(71) Applicant: Unimicron Technology Corp., Taoyuan City (TW)

(72) Inventors: Chin-Sheng Wang, Taoyuan City (TW); Chih-Kai Chan, Taoyuan City (TW); Shih-Lian Cheng, New Taipei City (TW); Ra-Min Tain, Hsinchu County (TW); Cheng-Ta Ko, Taipei City (TW); Pu-Ju Lin, Hsinchu City (TW)

(73) Assignee: Unimicron Technology Corp., Taoyuan City (TW)

(21) Appl. No.: 19/309,529

(22) Filed: Aug. 25, 2025

Related U.S. Application Data
(63) Continuation-in-part of application No. 19/023,397, filed on Jan. 16, 2025.
Application No. 19/023,397 is a continuation-in-part of application No. 18/677,924, filed on May 30, 2024.
(60) Provisional application No. 63/623,823, filed on Jan. 23, 2024.
(60) Provisional application No. 63/666,227, filed on Jun. 30, 2024.
(60) Provisional application No. 63/699,160, filed on Sep. 26, 2024.

(30) Foreign Application Priority Data
Apr. 30, 2024 (TW) 113116076
Nov. 14, 2024 (TW) 113143769
Aug. 11, 2025 (TW) 114130495

(51) Int. Cl. H05K 1/14; H05K 1/03; H05K 1/11; H05K 3/36

(52) U.S. Cl. CPC H05K 1/144; H05K 1/0306; H05K 1/115; H05K 3/368; H05K 2201/0129; H05K 2201/09536; H05K 2201/09563; H05K 2201/0959; H05K 2201/096; H05K 2201/09627; H05K 2201/1031; H05K 2203/0278; H05K 2203/1105

(57) ABSTRACT

A substrate structure includes a first substrate, a second substrate, a first conductive paste, and a first bonding layer. The first substrate includes a first core layer and a first conductive member. The second substrate includes a second core layer and a second conductive member. The first bonding layer confines the first conductive paste between the first conductive member and the second conductive member, such that the first conductive paste is in direct contact with the first conductive member and the second conductive member respectively, and the first bonding layer is in direct contact with the first core layer and the second core layer respectively. A manufacturing method of a substrate structure is also provided.

### CROSS-REFERENCE TO RELATED APPLICATION

This application is a continuation-in-part application of and claims the priority benefit of a prior application U.S. application Ser. No. 19/023,397, filed on Jan. 16, 2025, now pending. The prior U.S. application Ser. No. 19/023,397 is a continuation-in-part application of and claims the priority benefit of U.S. application Ser. No. 18/677,924, filed on May 30, 2024, now pending, which claims the priority benefits of U.S. provisional application Ser. No. 63/623,823, filed on Jan. 23, 2024, and Taiwan application serial no. 113116076, filed on Apr. 30, 2024. The prior U.S. application Ser. No. 18/677,924 also claims the priority benefit of U.S. provisional application Ser. No. 63/666,227, filed on Jun. 30, 2024, and Taiwan application serial no. 113143769, filed on Nov. 14, 2024. This application also claims the priority benefit of U.S. provisional application Ser. No. 63/699,160, filed on Sep. 26, 2024, and Taiwan application serial no. 114130495, filed on Aug. 11, 2025. The entirety of each of the above-mentioned patent applications is hereby incorporated by reference herein and made a part of this specification.

### BACKGROUND

### Technical Field

The disclosure relates to a substrate structure and a manufacturing method thereof.

### Description of Related Art

In the current substrate structure, manufacturing vias with a high aspect ratio has difficulties. For example, conductive materials usually cannot be reliably formed within openings with a high aspect ratio. As a result, this may adversely affect the electrical performance of the substrate structure and reduce the product reliability.

### SUMMARY

The disclosure provides a substrate structure and a manufacturing method thereof, which may effectively enhance product reliability.

A substrate structure of the disclosure includes a first substrate, a second substrate, a first conductive paste, and a first bonding layer. The first substrate includes a first core layer and a first conductive member. The second substrate includes a second core layer and a second conductive member. The first bonding layer confines the first conductive paste between the first conductive member and the second conductive member, such that the first conductive paste is in direct contact with the first conductive member and the second conductive member respectively, and the first bonding layer is in direct contact with the first core layer and the second core layer respectively.

A manufacturing method of a substrate structure of the disclosure includes at least the following steps. A first substrate is provided, where the first substrate includes a first core layer and a first conductive member penetrating therethrough. A first bonding layer is formed on the first substrate. A portion of the first bonding layer is removed to form a first opening exposing a first conductive surface of the first conductive member, where a bottom area of the first opening is less than or equal to a top area of the first conductive surface. A first conductive paste is formed within the first opening. A second substrate is provided. The first conductive paste is made to correspond to a second conductive member so as to bond the first substrate and the second substrate by a first heating process and a first pressing process.

Based on the above, the disclosure confines the setting position of the conductive paste through the opening of the bonding layer. In this way, when bonding two substrates, the stress issues generated by the conductive paste may be improved, reducing adverse effects on electrical performance. Moreover, using conductive paste as a bonding intermediate component may overcome the problem of uneven surface height when using direct metal-to-metal bonding, thereby effectively enhancing product reliability.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 to FIG. 8 are schematic partial cross-sectional views of a partial manufacturing method of a substrate structure according to some embodiments of the disclosure.

FIG. 9 is a schematic partial cross-sectional view of a substrate structure according to some embodiments of the disclosure.

FIG. 10 to FIG. 11 are schematic partial cross-sectional views of a partial manufacturing method of a substrate structure according to some embodiments of the disclosure.

FIG. 12 is a schematic partial cross-sectional view of a substrate structure according to some embodiments of the disclosure.

### DESCRIPTION OF THE EMBODIMENTS

In the following detailed description, for purposes of illustration and not limitation, exemplary embodiments disclosing specific details are set forth in order to provide a thorough understanding of various principles of the disclosure. However, it will be apparent to persons of ordinary skill in the art that the disclosure may be practiced in other embodiments that depart from the specific details disclosed herein, having the benefit of the disclosure. Moreover, the description of conventional devices, methods, and materials may be omitted so as not to obscure the description of the various principles of the disclosure.

The disclosure will be illustrated more comprehensively with reference to the drawings of the embodiments. However, the disclosure may also be embodied in many different forms and should not be construed as limited to the embodiments set forth herein. Thicknesses, dimensions, or sizes of layers or regions may be enlarged in the drawings for clarity. The same or similar reference numbers denote the same or similar components, and will not be repeatedly described in the following paragraphs.

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

Unless otherwise stated, the term “between” used in this specification to define numerical ranges is intended to cover ranges equal to and between the stated endpoints. For instance, if a size range is between a first value and a second value, the size range may cover the first value, the second value, and any value between the first value and the second value.

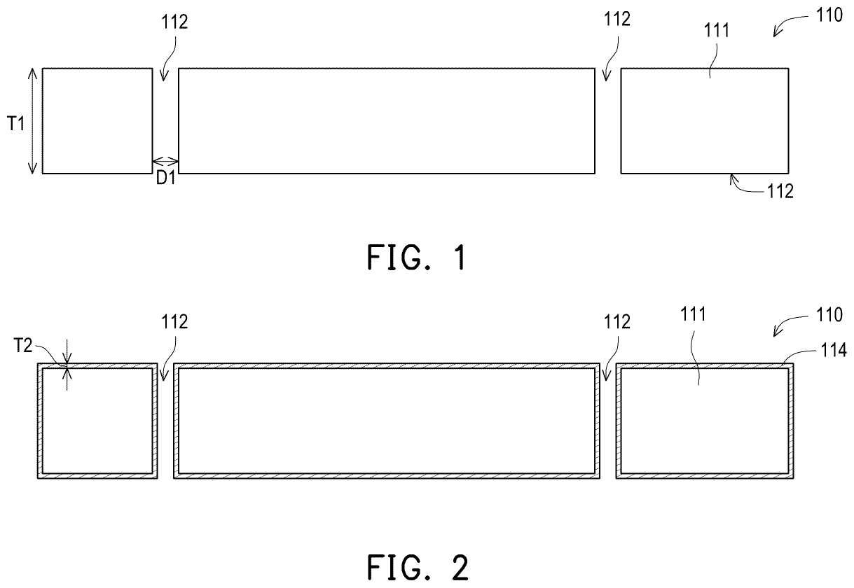

In the present embodiment, the manufacturing process of the substrate structure may include the following steps. Referring to FIG. 1, a first substrate 110 is provided. The first substrate 110 includes a first core layer 111 and at least one via 112 penetrating through the first core layer 111 (two vias 112 are schematically illustrated in the drawing). In some embodiments, the first core layer 111 is an inorganic insulation substrate, and a material thereof includes glass, ceramic or the like. In some embodiments, a thickness Tl of the first core layer 111 is between 50 micrometers to 1000 micrometers (for example, between 100 micrometers to 400 micrometers). In some embodiments, the via 112 may be formed by mechanical drilling, laser drilling, etching or other suitable methods. In some embodiments, the via 112 may be a through glass via (TGV). A diameter D1 of the via 112 is between 10 micrometers to 200 micrometers (preferably between 20 micrometers to 150 micrometers).

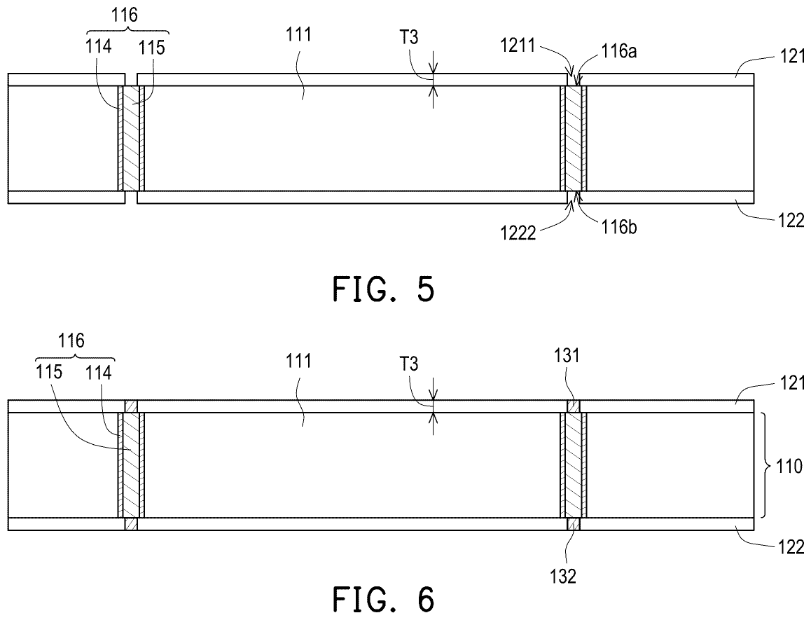

In some embodiments, a surface roughness of the top and bottom surfaces of the first substrate 110 is less than 10 nanometers or any other suitable value, so that the bonding layers subsequently formed thereon (such as the first bonding layer 121 and the second bonding layer 122 in FIG. 5) may have better film formation quality.

In an embodiment not illustrated, an insulation layer may be selectively formed on the first core layer 111 and the sidewalls of the via 112. The insulation layer may be an adhesion promotion layer (APL). Furthermore, the aforementioned insulation layer includes oxides, nitrides or a combination thereof, such as silicon dioxide (such as SiO₂ or SiOₓ), aluminum oxide (such as Al₂O₃), titanium oxide (such as TiO₂ or TiO or TiOₓ) or silicon nitride (Si₃N₄ or SiNₓ), but the disclosure is not limited thereto. A thickness of the insulation layer may be between 0.01 nanometers to 100 nanometers.

Referring to FIG. 2, in the present embodiment, a first conductive layer 114 may be formed on the first core layer 111 and the sidewalls of the via 112. The first conductive layer 114 may cover the insulation layer (if any). In some embodiments, the first conductive layer 114 may be referred to as a seed layer. In an embodiment, the first conductive layer 114 may include titanium-copper alloy, electroless plated metal or a combination thereof. The electroless plated metal may be formed by an electroless plating process, and a material thereof includes nickel-phosphorus, copper, silver or a combination thereof, but the disclosure is not limited thereto. In an embodiment, the first conductive layer 114 is formed using dry processes and/or wet processes.

For example, a sputtering process may be used first and then an electroless plating process may be used to completely cover the sidewalls of the via 112. In some embodiments, a thickness T2 of the first conductive layer 114 may be in a range of less than 1 micrometer.

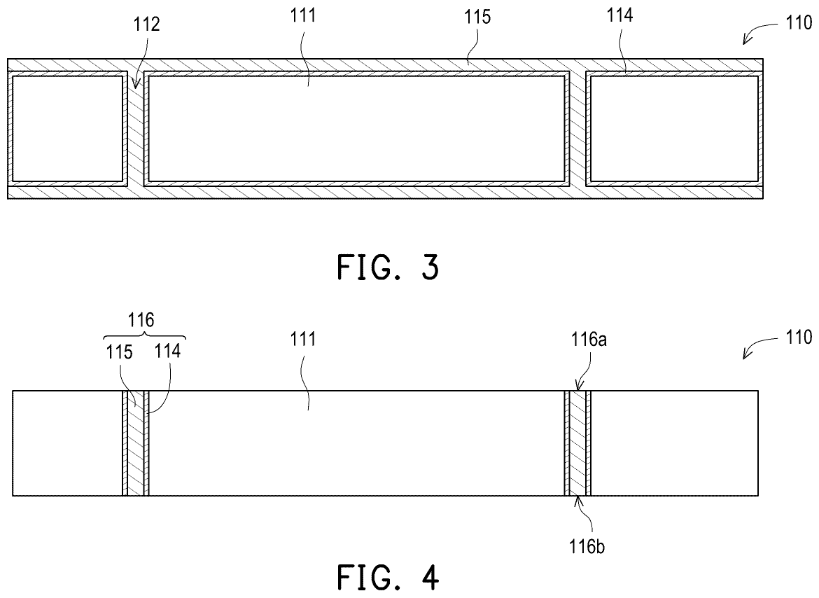

Referring to FIG. 3, a second conductive layer 115 is formed at least within the via 112. The second conductive layer 115 may be formed on the first conductive layer 114. In the present embodiment, the second conductive layer 115 may be a copper layer, and the second conductive layer 115 may be formed by electroplating.

Referring to FIG. 4, a portion of the first conductive layer 114 and a portion of the second conductive layer 115 outside the via 112 are removed. The removal method is, for example, a chemical mechanical polishing (CMP) process or other suitable removal processes. Furthermore, the first conductive layer 114 and the second conductive layer 115 within the via 112 may be retained to form a first conductive member 116, that is, the first conductive member 116 in the first substrate 110 includes the first conductive layer 114 and the second conductive layer 115, and the first conductive member 116 penetrates through the first core layer 111. In some embodiments, in FIG. 4, the plurality of first conductive members 116 may be electrically separated from each other.

It is worth noting that FIG. 4 or other similar Figure(s) may only illustrate a portion of an embodiment or a cross-section of a portion in an embodiment. In an embodiment not shown or on a cross-section not shown, a portion of the first conductive layer 114 and a portion of the second conductive layer 115 may still be retained on the upper surface (upper side in the drawings) or the lower surface (lower side in the drawings) of the first core layer 111. These retained portions of the first conductive layer 114 and the second conductive layer 115 may have corresponding patterns and may form appropriate circuits (for example, these may be referred to as circuit layers) or marks (for example, these may be referred to as alignment marks).

Referring to FIG. 5, a first bonding layer 121 may be formed on a first side of the first core layer 111, and then a portion of the first bonding layer 121 is removed to form a first opening 1211 that exposes a first conductive surface 116a of the first conductive member 116. The opening 1211 of the first bonding layer 121 may correspond to a position where conductive paste is to be formed, such as the position of the first conductive paste 131 as illustrated in FIG. 6. Furthermore, in order to enhance the formation quality of the first conductive paste 131, the dimensions of the first opening 1211 may be designed. For example, a bottom area of the first opening 1211 is less than or equal to a top area of the first conductive surface 116a. In some embodiments, an area ratio of the aforementioned bottom area to top area is between 0.25 and 1, so as to achieve better position-defining technical effects in subsequent processes. In some embodiments, a thickness T3 of the first bonding layer 121 is between 5 micrometers and 50 micrometers. Here, the first side of the first core layer 111 may be the upper side in the drawings, also referred to as the top.

In some embodiments, a material of the first bonding layer 121 includes thermoplastic polymer, thermosetting polymer, photoimageable dielectric (PID) material or a combination thereof. When the first bonding layer 121 is a thermoplastic polymer/thermosetting polymer, such as polyimide (PI) polymer, a laser process may be used to form the first opening 1211, and when the first bonding layer 121 is a photoimageable dielectric material, a photolithography and etching process may be used to form the first opening 1211.

Referring to FIG. 6, a first conductive paste 131 is formed in the first opening 1211. In some embodiments, a material of the first conductive paste 131 includes silver, copper, tin, bismuth or an alloy thereof. For example, the first conductive paste 131 may be suitable silver paste or low melting point materials such as copper core balls with surface-plated tin or bismuth, so as to reduce the process temperature during subsequent bonding.

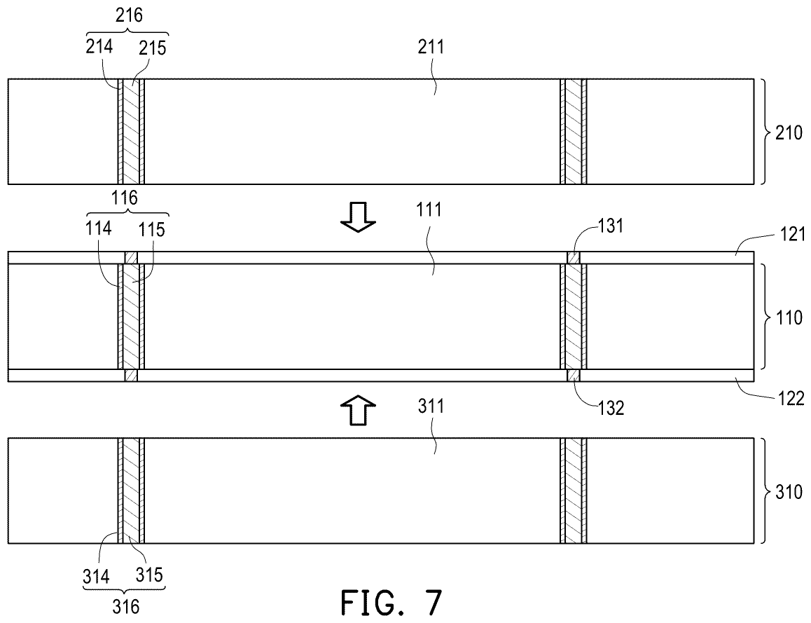

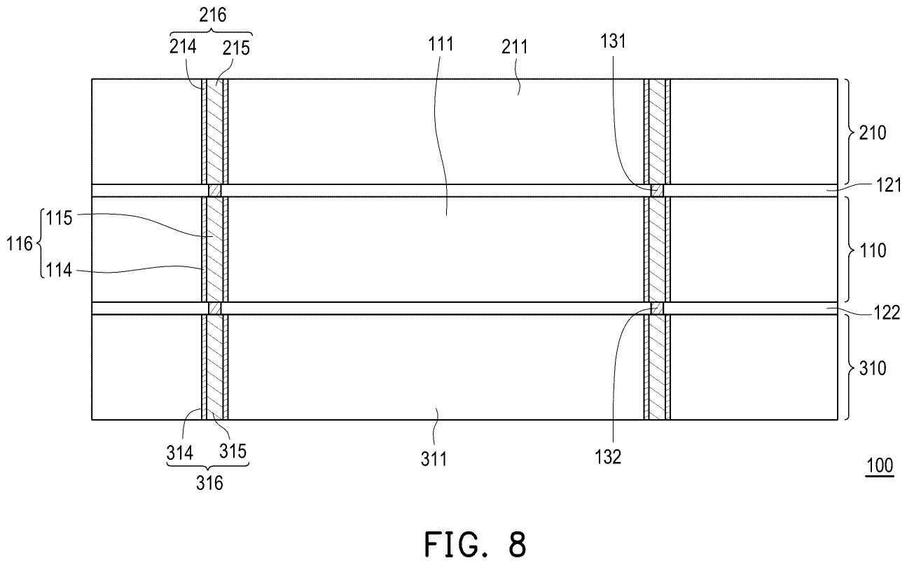

Referring to FIG. 7 and FIG. 8, a second substrate 210 similar to the first substrate 110 is provided. For example, the second substrate 210 includes a second core layer 211 and a second conductive member 216 penetrating therethrough, and the second conductive member 216 includes a third conductive layer 214 and a fourth conductive layer 215. The third conductive layer 214 and the fourth conductive layer 215 may be similar to the first conductive layer 114 and the second conductive layer 115, respectively. Next, the first conductive paste 131 is made to correspond to the second conductive member 216, so as to bond the first substrate 110 and the second substrate 210 by a first heating process and a first pressing process. In this way, the first bonding layer 121 may confine the first conductive paste 131 between the first conductive member 116 and the second conductive member 216, such that the first conductive paste 131 is in direct contact with the first conductive member 116 and the second conductive member 216 respectively (electrical connections may be formed between these components), and the first bonding layer 121 is in direct contact with the first core layer 111 and the second core layer 211 respectively. Through the above manufacturing process, a substrate structure 100 of the embodiment is substantially completed. Accordingly, the embodiment confines the setting position of the first conductive paste 131 through the first opening 1211 of the first bonding layer 121. In this way, when bonding the first substrate 110 and the second substrate 210, the stress issues generated by the first conductive paste 131 may be improved, thereby reducing adverse effects on electrical performance. When the first conductive paste 131 is used as a bonding intermediary, it may also overcome the problem of surface height unevenness caused by using direct metal-to-metal (such as copper-to-copper) bonding, such that product reliability may be effectively enhanced. Here, an intermetallic compound (IMC) alloy interface may be formed after the above bonding.

In some embodiments, an operating temperature of the first heating process is greater than or equal to a melting temperature of the first conductive paste 131, so as to enhance its bonding quality, and after bonding, the first bonding layer 121 and/or the first conductive paste 131 is completely cured to achieve the effect of final connection. In some embodiments, a temperature range of the first heating process is between 160° C. and 210° C. In some embodiments, a pressure range of the first pressing process is between 1 atm and 20 atm.

Referring again to FIG. 5 to FIG. 8, if based on requirements, the via aspect ratio of the substrate structure is to be further increased, the above method may be used to form a second bonding layer 122 and a second conductive paste 132 on a second side of the first core layer 111, and then bond the first substrate 110 and a third substrate 310 through the second bonding layer 122 and the second conductive paste 132. Furthermore, the third substrate 310 includes a third core layer 311 and a third conductive member 316. The third conductive member 316 includes a fifth conductive layer 314 and a sixth conductive layer 315. The fifth conductive layer 314 and the sixth conductive layer 315 may be similar to the first conductive layer 114 and the second conductive layer 115, respectively. Here, the second side of the first core layer 111 may be the lower side in the drawings, also referred to as the bottom.

For example, the second bonding layer 122 may be first formed on the first substrate 110, and then a portion of the second bonding layer 122 is removed to form a second opening 1222 that exposes a second conductive surface 116b. A top area of the second opening 1222 is less than or equal to a bottom area of the second conductive surface 116b. Next, the second conductive paste 132 is formed in the second opening 1222, and then the second conductive paste 132 is made to correspond to the third conductive member 316, so as to bond the first substrate 110 and the third substrate 310 by a second heating process and a second pressing process. In this way, the second bonding layer 122 confines the second conductive paste 132 between the first conductive member 116 and the third conductive member 316, such that the second conductive paste 132 is in direct contact with the first conductive member 116 and the third conductive member 316 respectively (electrical connections may be formed between these components), and the second bonding layer 122 is in direct contact with the first core layer 111 and the third core layer 311 respectively.

In some embodiments, the second substrate 210 and the third substrate 310 may be bonded in a same suitable high-temperature pressing process. Therefore, the first heating process and the second heating process use a same temperature, and the first pressing process and the second pressing process use a same pressure. It should be noted that the disclosure does not limit the number of substrates for bonding, as long as at least two substrates have any of the above bonding aspects, it belongs to the protection scope of the disclosure.

It should be noted that reference numbers of the components and a part of contents of the aforementioned embodiment are also used in the following embodiment, where the same or similar reference numbers denote the same or similar components, and descriptions of the same technical contents are omitted. The aforementioned embodiment may be referred for descriptions of the omitted parts, and detailed descriptions thereof are not repeated in the following embodiment.

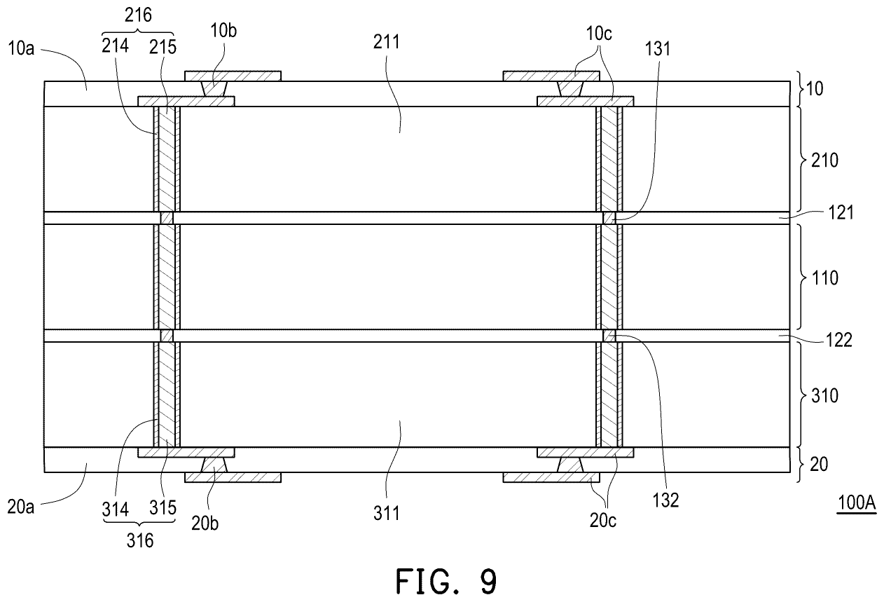

Referring to FIG. 9, similar to FIG. 8, the difference lies in that: a substrate structure 100A of the embodiment further forms a first build-up structure 10 and a second build-up structure 20 on surfaces of the second substrate 210 and the third substrate 310 opposite to the first substrate 110. For example, the first build-up structure 10 includes at least one dielectric layer (one dielectric layer 10a is schematically shown), at least one conductive blind via (two conductive blind vias 10b are schematically shown), and at least one circuit (two circuits 10c are schematically shown). The dielectric layer 10a is located on the second core layer 211, and the conductive blind via 10b is located in the dielectric layer 10a and is electrically connected to the circuit 10c and the second conductive member 216. On the other hand, the second build-up structure 20 includes at least one dielectric layer (one dielectric layer 20a is schematically shown), at least one conductive blind via (two conductive blind vias 20b are schematically shown), and at least one circuit (two circuits 20c are schematically shown). The dielectric layer 20a is located on the third core layer 311, and the conductive blind via 20b is located in the dielectric layer 20a and is electrically connected to the circuit 20c and the third conductive member 316. Through the setting of the first build-up structure 10 and the second build-up structure 20, a fan-out structure may be formed, thereby enhancing the applicability of the substrate structure 100A.

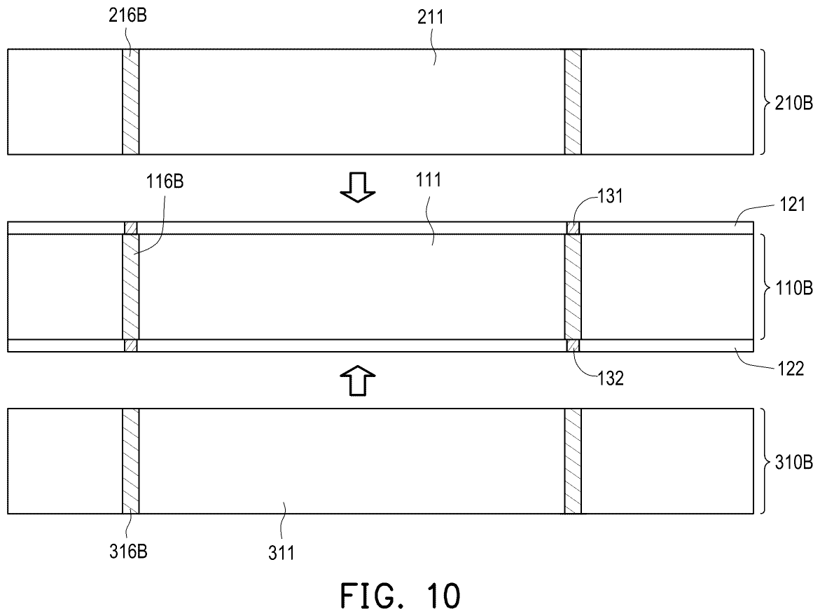

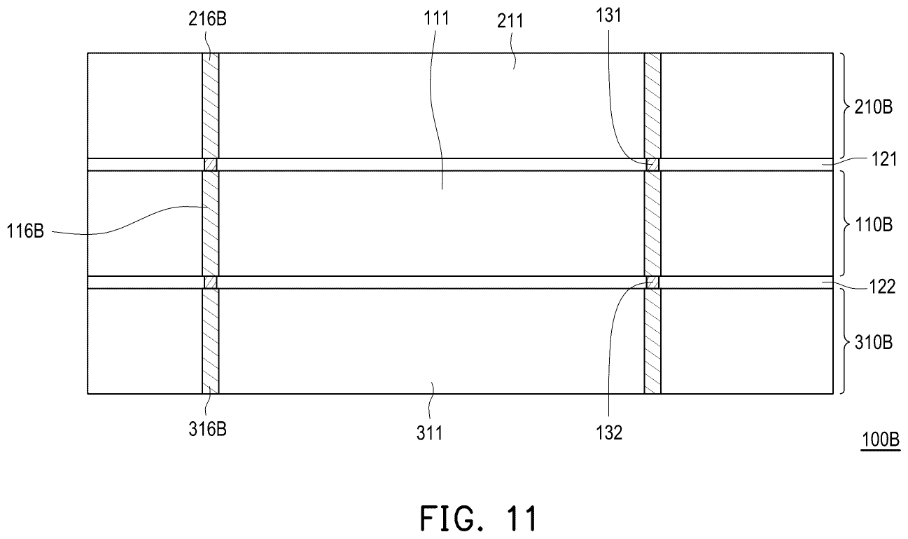

Referring to FIG. 10 to FIG. 11, similar to FIG. 7 to FIG. 8, the difference lies in that: a substrate structure 100B of the embodiment omits the seed layer. Further, a first conductive member 116B in a first substrate 110B of the embodiment omits the first conductive layer 114 as in FIG. 7, a second conductive member 216B in a second substrate 210B omits the third conductive layer 214 as in FIG. 7, and a third conductive member 316B in a third substrate 310B omits the fifth conductive layer 314 as in FIG. 7. In some embodiments, after the via 112 of FIG. 1 is formed, conductive paste or the like may be directly filled in the via 112 to form the first conductive member 116B that fills the via 112 in one time, and the second conductive member 216B and the third conductive member 316B may also be formed through similar methods. The conductive paste in the via 112 may be composed of materials different from the first conductive paste 131 and the second conductive paste 132.

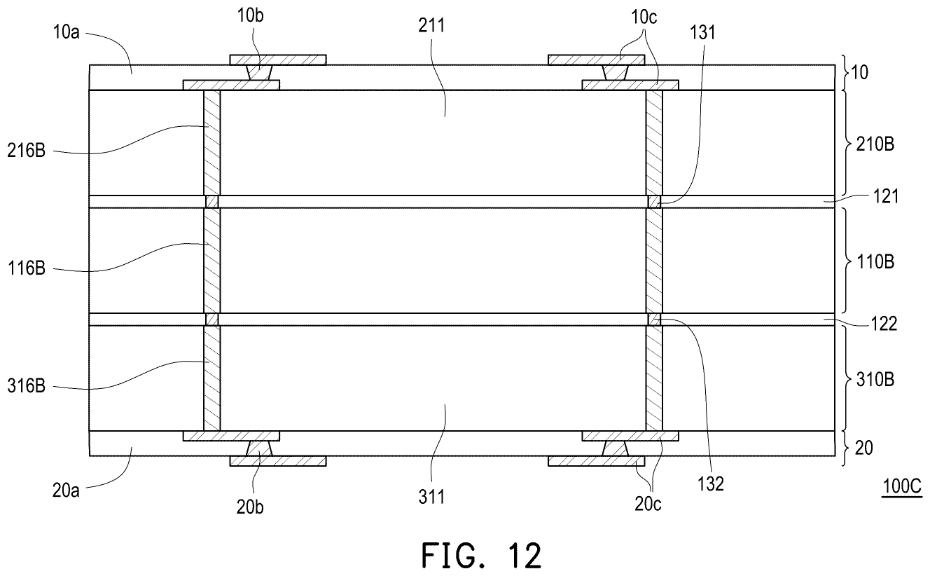

Referring to FIG. 12, similar to FIG. 9 and FIG. 11, the difference lies in that: a substrate structure 100C of the embodiment further forms a first build-up structure 10 and a second build-up structure 20 on surfaces of the second substrate 210B and the third substrate 310B opposite to the first substrate 110B, thereby enhancing the applicability of the substrate structure 100C.

It should be noted that, although the plurality of substrates in the same embodiment described above have the same structure, any person of ordinary skill in the art may also make adjustments according to actual design requirements. For example, the first substrate 110 may also be bonded with the second substrate 210B and the third substrate 310B.

In summary, the disclosure confines the setting position of the conductive paste through the opening of the bonding layer. In this way, when bonding two substrates, the stress issues generated by the conductive paste may be improved, reducing adverse effects on electrical performance. Moreover, using conductive paste as a bonding intermediate component may overcome the problem of uneven surface height when using direct metal-to-metal bonding, thereby effectively enhancing product reliability.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A substrate structure, comprising:
a first substrate, comprising a first core layer and a first conductive member;
a second substrate, comprising a second core layer and a second conductive member;
a first conductive paste; and
a first bonding layer, wherein the first bonding layer confines the first conductive paste between the first conductive member and the second conductive member, such that the first conductive paste is in direct contact with the first conductive member and the second conductive member respectively, and the first bonding layer is in direct contact with the first core layer and the second core layer respectively.

2. The substrate structure according to claim 1, wherein a material of the first conductive paste comprises silver, copper, tin, bismuth or an alloy thereof.

3. The substrate structure according to claim 1, wherein a thickness of the first bonding layer is between 5 micrometers and 50 micrometers.

4. The substrate structure according to claim 1, wherein a material of the first bonding layer comprises thermoplastic polymer, thermosetting polymer, photoimageable dielectric material or a combination thereof.

5. The substrate structure according to claim 1, wherein a material of one or both of the first core layer and the second core layer comprises glass or ceramic.

6. The substrate structure according to claim 1, wherein a thickness of one or both of the first core layer and the second core layer is between 50 micrometers and 1000 micrometers.

7. The substrate structure according to claim 1, wherein one or both of the first conductive member and the second conductive member comprises a plurality of conductive layers.

8. The substrate structure according to claim 1, wherein one or both of the first conductive member and the second conductive member is formed by another conductive paste different from the first conductive paste.

9. The substrate structure according to claim 1, further comprising a first build-up structure, disposed on a surface of the second substrate opposite to the first substrate.

10. The substrate structure according to claim 1, further comprising:
a third substrate, comprising a third core layer and a third conductive member;
a second conductive paste; and
a second bonding layer, wherein the second bonding layer confines the second conductive paste between the first conductive member and the third conductive member, such that the second conductive paste is in direct contact with the first conductive member and the third conductive member respectively, and the second bonding layer is in direct contact with the first core layer and the third core layer respectively.

11. The substrate structure according to claim 10, further comprising a second build-up structure, disposed on a surface of the third substrate opposite to the first substrate.

12. A manufacturing method of a substrate structure, comprising:
providing a first substrate, wherein the first substrate comprises a first core layer and a first conductive member penetrating therethrough, and the first conductive member comprises a first conductive surface and a second conductive surface opposite to each other;
forming a first bonding layer on the first substrate;
removing a portion of the first bonding layer to form a first opening exposing the first conductive surface, wherein a bottom area of the first opening is less than or equal to a top area of the first conductive surface;
forming a first conductive paste in the first opening;
providing a second substrate, wherein the second substrate comprises a second core layer and a second conductive member penetrating therethrough; and
making the first conductive paste correspond to the second conductive member, so as to bond the first substrate and the second substrate by a first heating process and a first pressing process.

13. The manufacturing method of the substrate structure according to claim 12, wherein an area ratio of the bottom area to the top area is between 0.25 and 1.

14. The manufacturing method of the substrate structure according to claim 12, wherein an operating temperature of the first heating process is greater than or equal to a melting temperature of the first conductive paste.

15. The manufacturing method of the substrate structure according to claim 12, wherein a temperature range of the first heating process is between 160° C. and 210° C.

16. The manufacturing method of the substrate structure according to claim 12, wherein a pressure range of the first pressing process is between 1 atm and 20 atm.

17. The manufacturing method of the substrate structure according to claim 12, wherein the first opening is formed through a laser process or a photolithography and etching process.

18. The manufacturing method of the substrate structure according to claim 12, further comprising:
forming a second bonding layer on the first substrate;
removing a portion of the second bonding layer to form a second opening exposing the second conductive surface, wherein a top area of the second opening is less than or equal to a bottom area of the second conductive surface;
forming a second conductive paste in the second opening;
providing a third substrate, wherein the third substrate comprises a third core layer and a third conductive member penetrating therethrough; and
making the second conductive paste correspond to the third conductive member, so as to bond the first substrate and the third substrate by a second heating process and a second pressing process.

19. The manufacturing method of the substrate structure according to claim 18, wherein the first heating process and the second heating process use a same temperature, and the first pressing process and the second pressing process use a same pressure.
